(19) United States
(12) Patent Application Publication
(10) Pub. No.: US 2026/0157146 A1
(43) Pub. Date: Jun. 4, 2026

(54) ELECTROSTATIC CHUCK, SUBSTRATE FIXING DEVICE, AND METHOD FOR MANUFACTURING ELECTROSTATIC CHUCK

(71) Applicant: SHINKO ELECTRIC INDUSTRIES CO., LTD., Nagano-shi (JP)

(72) Inventors: Takuya Muramatsu, Kanagawa (JP); Yusuke Kinoshita, Nagano (JP)

(21) Appl. No.: 19/402,083

(22) Filed: Nov. 26, 2025

(30) Foreign Application Priority Data
Nov. 29, 2024 (JP) 2024-208476

(51) Int. Cl. H10P 72/72; H01J 37/32

(52) U.S. Cl. CPC H10P 72/722; H01J 37/32715; H01J 2237/2007

(57) ABSTRACT

An electrostatic chuck consists of an insulating substrate with a placement surface for holding an object and an opposite surface on the reverse side. A gas hole passes through the substrate in the thickness direction and features a first hole that extends from the opposite surface, a first enlarged space expanding the gas hole in a planar direction, and a second hole extending toward the placement surface from the enlarged space. The first hole and second hole are arranged to avoid overlap in a plan view. The planar size of the enlarged space exceeds the combined planar sizes of the first and second holes. Additionally, the dimension of the enlarged space in the thickness direction is smaller than the dimension of the first hole in the planar direction. This design optimizes adsorption and gas flow control, ensuring effective placement of the object and reliable chuck operation.

### TECHNICAL FIELD

The present invention relates to an electrostatic chuck, a substrate fixing device, and a method for manufacturing an electrostatic chuck.

### BACKGROUND ART

In the related art, a film forming device or a plasma etching device used for manufacturing a semiconductor device includes a stage for accurately holding a wafer in a vacuum processing chamber. As the stage, for example, a substrate fixing device that adsorbs and holds a wafer by an electrostatic chuck mounted on a base plate has been proposed.

As an example of the substrate fixing device, there is a substrate fixing device having a structure in which a gas supply unit for cooling a wafer is provided (for example, see JP2017-218352A).

The gas supply unit supplies gas to a surface of the electrostatic chuck through a gas flow path provided in the base plate and a gas hole provided in the electrostatic chuck. The gas flow path is formed to extend linearly along a thickness direction of the base plate. The gas hole is formed to extend linearly along a thickness direction of the electrostatic chuck.

### SUMMARY OF INVENTION

In the above substrate fixing device, it is desired to prevent occurrence of abnormal discharge in the gas supply unit.

According to one aspect of the present disclosure, an electrostatic chuck includes an insulating substrate having a placement surface on which an object to be adsorbed is placed and an opposite surface provided on an opposite side of the placement surface, and a gas hole penetrating the insulating substrate in a thickness direction. The gas hole includes a first hole portion that extends from the opposite surface toward the placement surface, a first enlarged space that communicates with the first hole portion and expands a space of the gas hole in a planar direction orthogonal to the thickness direction, and a second hole portion that communicates with the first enlarged space and extends from the first enlarged space toward the placement surface. The first hole portion is provided so as not to overlap the second hole portion in a plan view. A planar size of the first enlarged space is larger than a planar size obtained by combining a planar size of the first hole portion and a planar size of the second hole portion. A dimension of the first enlarged space along the thickness direction is smaller than a dimension of the first hole portion along the planar direction.

According to one aspect of the present invention, an effect is achieved in that the occurrence of abnormal discharge can be prevented.

### BRIEF DESCRIPTION OF DRAWINGS

FIG. 1 is a schematic sectional view (sectional view taken along a line 1-1 in FIG. 2) illustrating a substrate fixing device according to an embodiment.

FIG. 2 is a schematic plan view illustrating the substrate fixing device according to the embodiment.

FIG. 3 is an exploded perspective view illustrating an electrostatic chuck according to the embodiment.

FIG. 4 is a schematic plan view illustrating each insulating layer of the electrostatic chuck according to the embodiment.

FIG. 5 is a schematic sectional view illustrating a method for manufacturing an electrostatic chuck according to the embodiment.

FIG. 6 is a schematic sectional view illustrating the method for manufacturing an electrostatic chuck according to the embodiment.

FIG. 7 is a schematic sectional view illustrating the method for manufacturing an electrostatic chuck according to the embodiment.

FIG. 8 is a schematic sectional view illustrating the method for manufacturing an electrostatic chuck according to the embodiment.

FIG. 9 is a schematic sectional view illustrating the method for manufacturing an electrostatic chuck according to the embodiment.

FIG. 10 is a schematic sectional view illustrating the method for manufacturing an electrostatic chuck according to the embodiment.

FIG. 11 is an exploded perspective view illustrating an electrostatic chuck according to a modification.

### DESCRIPTION OF EMBODIMENTS

Hereinafter, an embodiment will be described with reference to the accompanying drawings.

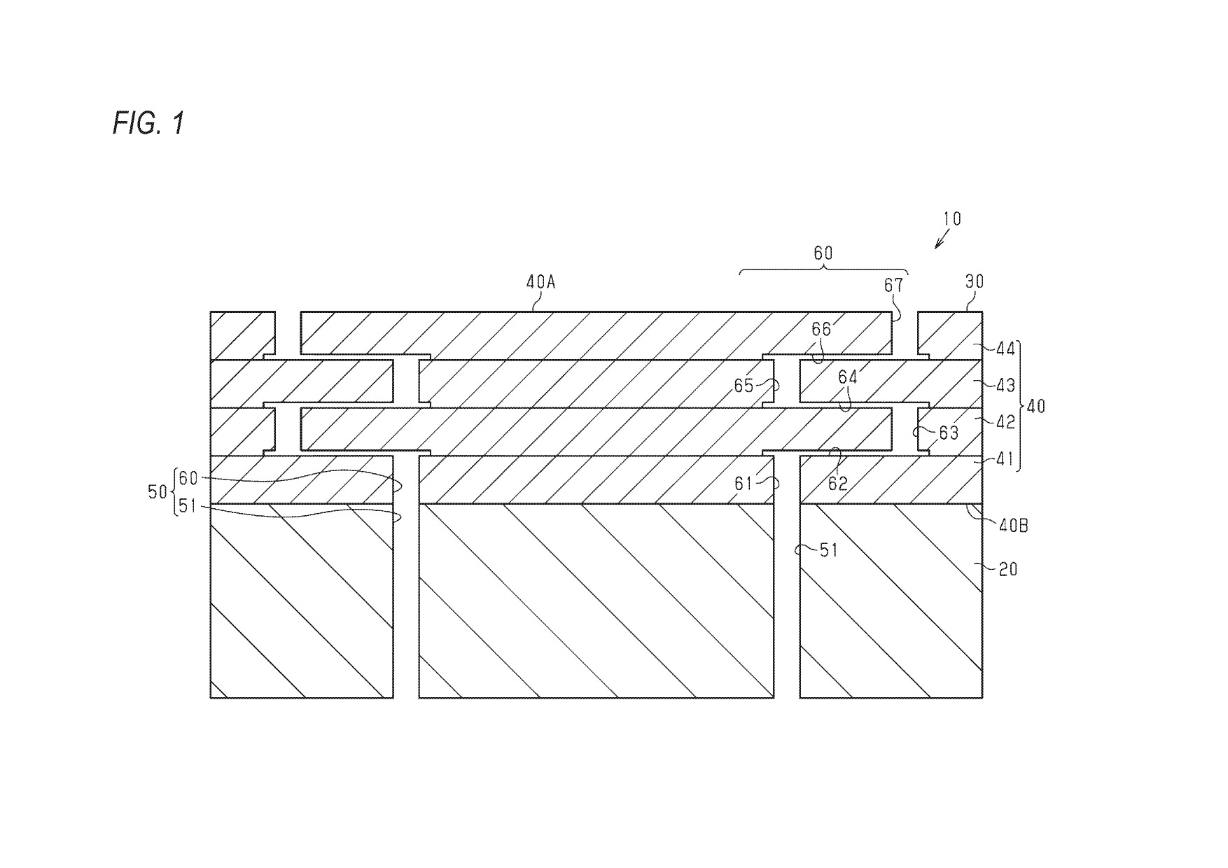

In addition, in the accompanying drawings, for the sake of convenience, a portion serving as characteristics may be illustrated in an enlarged manner in order to facilitate understanding of the characteristics, and a dimensional ratio of each component may be different in each drawing. In the sectional views, in order to facilitate understanding of a sectional structure of each member, hatching of some members is illustrated instead of a satin pattern, and hatching of some members is omitted. In the present specification, a "plan view" refers to viewing an object from a vertical direction (upper-lower direction in the drawing) in FIG. 1 and the like, and a "planar shape" refers to a shape of the object viewed from the vertical direction in FIG. 1 and the like. The "upper-lower direction" and a "left-right direction" in the present specification are directions in a case where a direction in which a reference sign indicating each member is correctly readable in each drawing is a positive position. Unless otherwise described, a numerical range of "X1 to X2" defined by an upper limit value X1 and a lower limit value X2 in the description of the present disclosure means X1 or more and X2 or less.

### Overall Configuration of Substrate Fixing Device 10

As illustrated in FIG. 1, the substrate fixing device 10 includes a base plate 20, an electrostatic chuck 30 disposed on the base plate 20, and gas supply units 50. The electrostatic chuck 30 is bonded to an upper surface of the base plate 20 by an adhesive such as a silicone resin. The electrostatic chuck 30 may be fixed to the base plate 20 by screws. An object to be adsorbed (not illustrated) is placed on an upper surface of the electrostatic chuck 30. Examples of the object to be adsorbed include a wafer. A diameter of the wafer can be, for example, about 8 inches, 12 inches, or 18 inches. The substrate fixing device 10 adsorbs and holds an object to be adsorbed placed on the electrostatic chuck 30.

### Configuration of Base Plate 20

The base plate 20 is a base body (base) on which the electrostatic chuck 30 is mounted. The base plate 20 has rigidity for supporting the electrostatic chuck 30. As a material of the base plate 20, for example, a metal material such as aluminum or cemented carbide, a composite material of the metal material and a ceramic material, or the like can be used. In the present embodiment, aluminum or an aluminum alloy is used, and a surface thereof is subjected to an alumite treatment from a viewpoint of easy availability, ease of processing, and good thermal conductivity.

The base plate 20 may have any shape and any size. The base plate 20 is formed in, for example, a disk shape in accordance with a shape of the object to be adsorbed placed on the electrostatic chuck 30. A diameter of the base plate 20 can be, for example, about 150 mm to 500 mm. A thickness of the base plate 20 can be, for example, about 10 mm to 50 mm. As used herein, the term "disk shape" refers to a circular planar shape having a predetermined thickness. In the "disk shape", the thickness relative to the diameter does not matter. The term "disk shape" also includes a shape in which a recess or a protrusion is partially formed.

### Configuration of Electrostatic Chuck 30

The electrostatic chuck 30 includes an insulating substrate 40 having a placement surface 40A on which an object to be adsorbed is placed and an opposite surface 40B provided on an opposite side of the placement surface 40A, and an electrode (not illustrated) built in the insulating substrate 40. The electrostatic chuck 30 is a holder that adsorbs and holds the wafer which is the object to be adsorbed. The electrode (not illustrated) is, for example, an electrostatic electrode for adsorbing the object to be adsorbed placed on the placement surface 40A of the insulating substrate 40. The electrode adsorbs and holds the object to be adsorbed on the placement surface 40A by, for example, an electrostatic force generated by a voltage applied from an adsorption power supply provided outside the substrate fixing device 10. The electrostatic chuck 30 is, for example, a Johnsen-Rahbek type electrostatic chuck. However, the electrostatic chuck 30 may be a Coulomb force type electrostatic chuck.

### Configuration of Insulating Substrate 40

The insulating substrate 40 may have any shape and any size. The insulating substrate 40 is formed in a disk shape, for example. A diameter of the insulating substrate 40 may be, for example, equal to or smaller than the diameter of the base plate 20. The diameter of the insulating substrate 40 can be, for example, about 150 mm to 500 mm. A thickness of the insulating substrate 40 can be, for example, about 1 mm to 10 mm.

A material having an insulating property can be used as the material of the insulating substrate 40. As a material of the insulating substrate 40, a ceramic material such as aluminum oxide (Al₂O₃), aluminum nitride (AlN), or silicon nitride, or an organic material such as a silicone resin or a polyimide resin can be used. In the present embodiment, a ceramic material such as aluminum oxide or aluminum nitride is adopted as the material of the insulating substrate 40 from the viewpoint of easy availability, easy of processing, and relatively high resistance to plasma or the like. That is, the insulating substrate 40 according to the present embodiment is a ceramic substrate made of a ceramic material.

The insulating substrate 40 has, for example, a structure in which a plurality of (here, four) insulating layers 41, 42, 43, 44 are stacked. Each of the insulating layers 41, 42, 43, 44 is, for example, a sintered body formed by sintering a green sheet made of a mixture of aluminum oxide and an organic material. In each drawing, an interface between the insulating layer 41 and the insulating layer 42, an interface between the insulating layer 42 and the insulating layer 43, and an interface between the insulating layer 43 and the insulating layer 44 are indicated by solid lines. These interfaces are formed by stacking a plurality of green sheets, and may be different in position depending on a stacked state, may not be linear in a cross section, or may not be clear.

The placement surface 40A of the insulating substrate 40 is provided, for example, on an upper surface of the insulating layer 44. The opposite surface 40B of the insulating substrate 40 is provided, for example, on a lower surface of the insulating layer 41. The opposite surface 40B is bonded to the upper surface of the base plate 20 by, for example, an adhesive (not illustrated).

### Configuration of Gas Supply Unit 50

A plurality of gas supply units 50 are provided inside the base plate 20 and the electrostatic chuck 30. Each gas supply unit 50 is formed to penetrate the base plate 20 in the thickness direction (upper-lower direction in the drawing) and to penetrate the electrostatic chuck 30 in the thickness direction (upper-lower direction in the drawing). That is, each gas supply unit 50 penetrates from the lower surface of the base plate 20 to the upper surface (that is, the placement surface 40A) of the electrostatic chuck 30. Each gas supply unit 50 is formed to open below the base plate 20 and open above the electrostatic chuck 30. For example, gas for cooling the object to be adsorbed that is adsorbed and held on the placement surface 40A of the electrostatic chuck 30 is introduced into each gas supply unit 50. Inert gas may be used as gas for cooling. Examples of the inert gas include helium (He) gas and argon (Ar) gas.

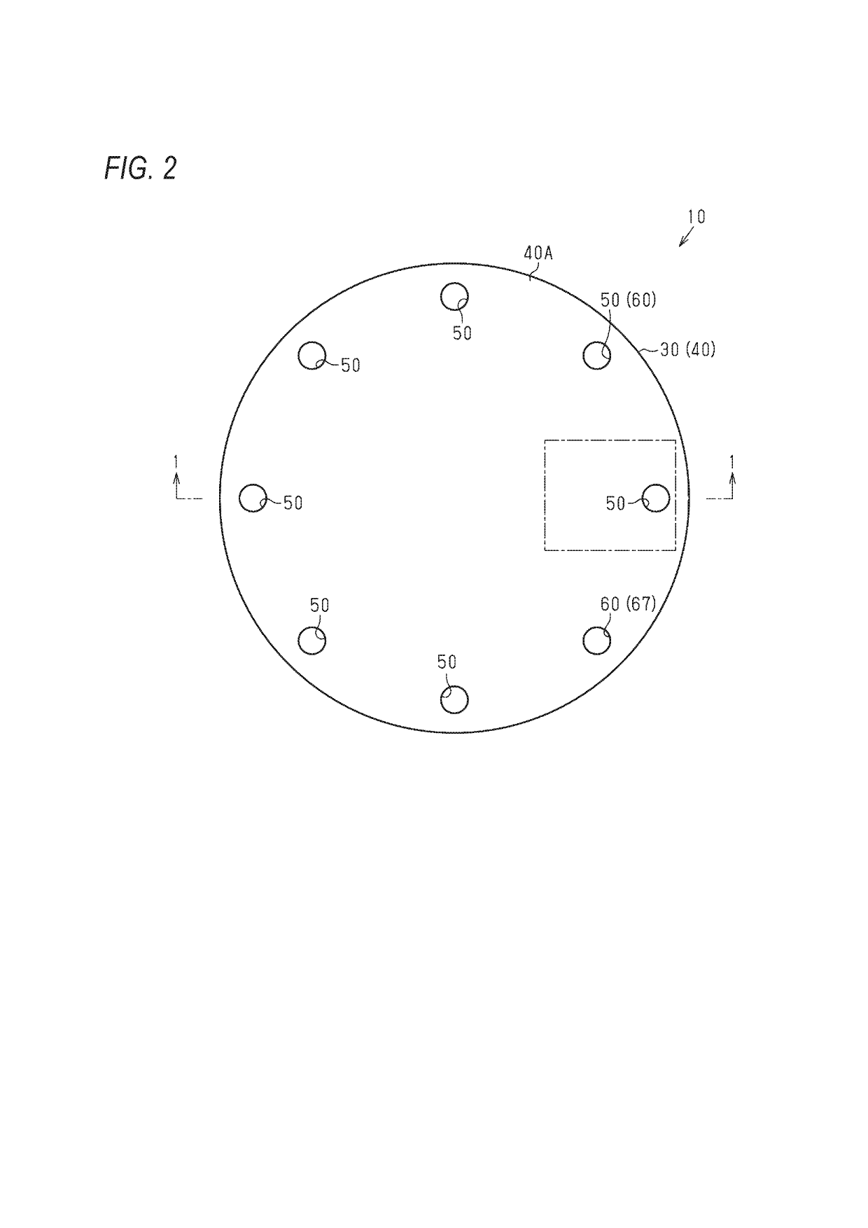

As illustrated in FIG. 2, for example, the plurality of gas supply units 50 are scattered on the placement surface 40A of the electrostatic chuck 30 in a plan view. In this example, eight gas supply units 50 are arranged along an outer peripheral edge of the electrostatic chuck 30 in a plan view. The number of gas supply units 50 can be appropriately determined as necessary. For example, the number of gas supply units 50 can be about several tens to several hundreds.

As illustrated in FIG. 1, each gas supply unit 50 includes a gas flow path 51 provided in the base plate 20 and a gas hole 60 provided in the insulating substrate 40 of the electrostatic chuck 30. Each gas supply unit 50 is formed to penetrate from the lower surface of the base plate 20 to the placement surface 40A of the insulating substrate 40 by communicating the gas flow path 51 and the gas hole 60 with each other. In each gas supply unit 50, a lower end portion of the gas flow path 51 serves as an introduction port (inflow port) of the gas supply unit 50 into which the inert gas is introduced from a gas supply source (not illustrated). In each gas supply unit 50, an upper end portion of the gas hole 60 serves as a discharge port (outflow port) of the gas supply unit 50 from which the inert gas introduced into the gas supply unit 50 is discharged. In the gas supply unit 50, the inert gas is introduced into the gas supply unit 50 through the gas flow path 51, and the inert gas is discharged from the upper end portion of the gas hole 60 through the gas flow path 51 and the gas hole 60. The inert gas discharged from the upper end portion of the gas hole 60 can cool the object to be adsorbed by being filled between the object to be adsorbed placed on the placement surface 40A and the placement surface 40A, for example.

### Configuration of Gas Flow Path 51

The gas flow path 51 is formed to penetrate the base plate 20 in the thickness direction. That is, each gas flow path 51 penetrates from the lower surface of the base plate 20 to the upper surface of the base plate 20. Each gas flow path 51 is formed to open below the base plate 20 and open above the base plate 20.

### Configuration of Gas Hole 60

Each gas hole 60 is formed to penetrate the insulating substrate 40 of the electrostatic chuck 30 in the thickness direction (stacking direction). Each gas hole 60 penetrates from the opposite surface 40B of the insulating substrate 40 to the placement surface 40A of the insulating substrate 40. Each gas hole 60 is formed to communicate with the corresponding gas flow path 51. The inert gas is introduced into each gas hole 60 from the gas flow path 51. The plurality of gas holes 60 have the same structure. Therefore, in the following description, a specific structure of the gas hole 60 will be described by focusing on one gas hole 60 (see a one-dot chain line frame in FIG. 2).

Each gas hole 60 includes one or more hole portions 61 that penetrate the insulating layer 41 in the thickness direction, an enlarged space 62 that expands a space in a planar direction, one or more hole portions 63 that penetrate the insulating layer 42 in the thickness direction, and an enlarged space 64 that expands a space in the planar direction. Each gas hole 60 includes one or more hole portions 65 that penetrate the insulating layer 43 in the thickness direction, an enlarged space 66 that expands a space in the planar direction, and one or more hole portions 67 that penetrate the insulating layer 44 in the thickness direction. Each gas hole 60 according to the present embodiment includes one hole portion 61, one enlarged space 62, one hole portion 63, one enlarged space 64, one hole portion 65, one enlarged space 66, and one hole portion 67. Each gas hole 60 is formed to penetrate from the opposite surface 40B of the insulating substrate 40 to the placement surface 40A of the insulating substrate 40 by the hole portion 61, 63, 65, 67 and the enlarged space 62, 64, 66 communicating with each other. Here, the planar direction is a direction orthogonal to the thickness direction of the insulating substrate 40.

### Configuration of Hole Portion 61

The hole portion 61 is formed to be open below the insulating substrate 40. The hole portion 61 communicates with the gas flow path 51. The hole portion 61 is formed to extend from the opposite surface 40B of the insulating substrate 40 toward the placement surface 40A. The hole portion 61 is formed to extend linearly along the thickness direction of the insulating substrate 40, for example. An upper end portion of the hole portion 61 communicates with the enlarged space 62. The hole portion 61 may have any shape and size.

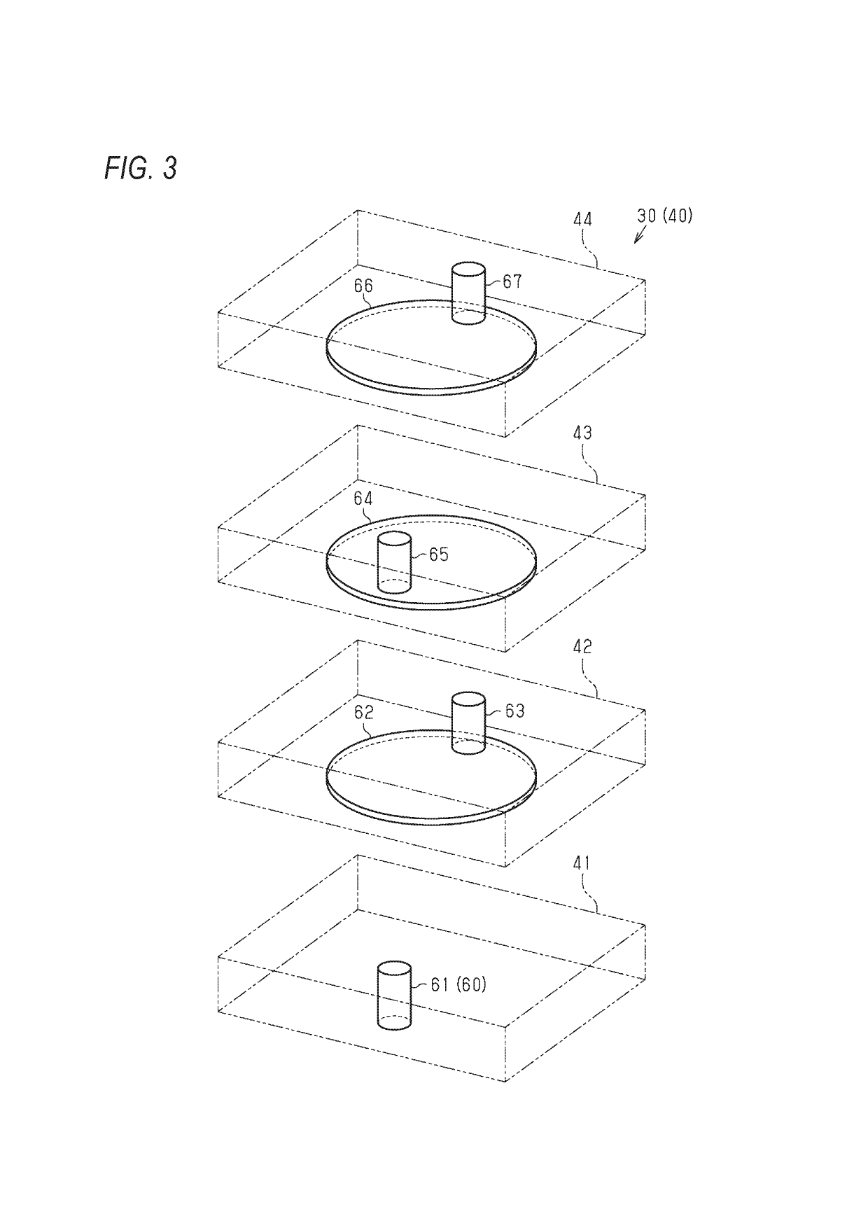

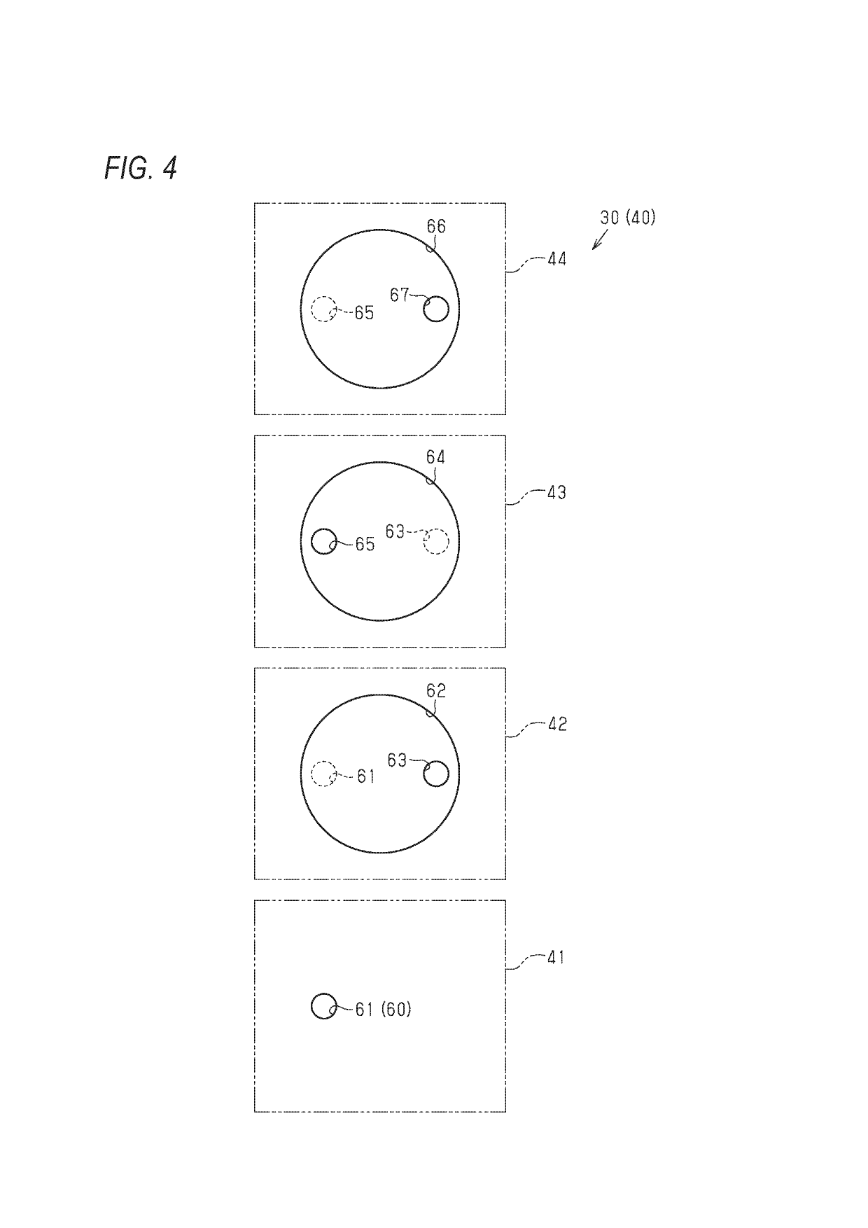

As illustrated in FIGS. 3 and 4, a planar shape of the hole portion 61 according to the present embodiment is formed in a circular shape. A planar size of the hole portion 61 is smaller than a planar size of the enlarged space 62. A diameter (opening diameter) of the hole portion 61 can be, for example, about 0.05 mm to 0.5 mm.

### Configuration of Enlarged Space 62

As illustrated in FIG. 1, the enlarged space 62 is provided between the insulating layer 41 and the insulating layer 42. The enlarged space 62 is formed so as to be surrounded by the insulating layer 41 and the insulating layer 42. The enlarged space 62 is provided, for example, on the upper surface of the insulating layer 41. The enlarged space 62 is, for example, recessed upward from the lower surface of the insulating layer 42. The enlarged space 62 is formed so as not to penetrate the insulating layer 42 in the thickness direction. The enlarged space 62 is formed to be open below the insulating layer 42, for example. A depth of the enlarged space 62 is smaller than the thickness of the insulating layer 42. That is, a dimension of the enlarged space 62 along the thickness direction of the insulating substrate 40 is smaller than a dimension of the insulating layer 42 along the thickness direction. A depth of the enlarged space 62 is smaller than the diameter of the hole portion 61. That is, a dimension of the enlarged space 62 along the thickness direction is smaller than a dimension of the hole portion 61 along the planar direction. The dimension of the enlarged space 62 along the thickness direction can be, for example, about 0.02 mm to 0.15 mm.

As illustrated in FIG. 4, the enlarged space 62 is formed to expand from the hole portion 61 in the planar direction. The enlarged space 62 is formed so as to surround the hole portion 61 and the hole portion 63 in a plan view. The enlarged space 62 is formed to expand in an area between the hole portion 61 and the hole portion 63 and to expand in an area outside the hole portions 61, 63 in a plan view. The enlarged space 62 may have any shape and size. A planar shape of the enlarged space 62 according to the present embodiment is formed in a circular shape. The planar size of the enlarged space 62 is larger than a planar size obtained by combining the planar size of the hole portion 61 and a planar size of the hole portion 63. The planar size of the enlarged space 62 may be, for example, about five to twelve times the planar size of the hole portion 61. A diameter of the enlarged space 62 can be, for example, about 1.0 mm to 3.0 mm.

### Configuration of Hole Portion 63

As illustrated in FIG. 1, a lower end portion of the hole portion 63 communicates with the enlarged space 62. The hole portion 63 is formed to extend from the enlarged space 62 toward the placement surface 40A, for example. The hole portion 63 is formed to extend linearly along the thickness direction of the insulating substrate 40, for example. The hole portion 63 is formed to extend from the enlarged space 62 to an upper surface of the insulating layer 42. An upper end portion of the hole portion 63 communicates with the enlarged space 64.

As illustrated in FIG. 4, the hole portion 63 is provided so as not to overlap the hole portion 61 in a plan view. For example, the hole portion 63 is provided at a position rotated by 180 degrees around a center point of the enlarged space 62 from the hole portion 61 in a plan view. The hole portion 63 is disposed such that a separation distance between the hole portion 61 and the hole portion 63 is as large as possible in an area overlapping the enlarged space 62 in a plan view.

The hole portion 63 may have any shape and size. A planar shape of the hole portion 63 according to the present embodiment is formed in a circular shape. The planar size of the hole portion 63 is set to, for example, the same size as the planar size of the hole portion 61. The planar size of the hole portion 63 is smaller than the planar size of the enlarged space 62. A diameter of the hole portion 63 may be, for example, about 0.05 mm to 0.5 mm.

### Configuration of Enlarged Space 64

As illustrated in FIG. 1, the enlarged space 64 is provided between the insulating layer 42 and the insulating layer 43. The enlarged space 64 is formed so as to be surrounded by the insulating layer 42 and the insulating layer 43. The enlarged space 64 is provided, for example, on the upper surface of the insulating layer 42. The enlarged space 64 is, for example, recessed upward from the lower surface of the insulating layer 43. The enlarged space 64 is formed so as not to penetrate the insulating layer 43 in the thickness direction. The enlarged space 64 is formed to be open below the insulating layer 43, for example. A dimension of the enlarged space 64 along the thickness direction is smaller than a dimension of the insulating layer 43 along the thickness direction. The dimension of the enlarged space 64 along the thickness direction is smaller than a dimension of the hole portion 63 along the planar direction. The dimension of the enlarged space 64 along the thickness direction can be, for example, about 0.02 mm to 0.15 mm.

As illustrated in FIG. 4, the enlarged space 64 is formed to expand from the hole portion 63 in the planar direction. The enlarged space 64 is formed so as to surround the hole portion 63 and the hole portion 65 in a plan view. The enlarged space 64 is formed to expand in an area between the hole portion 63 and the hole portion 65 and to expand in an area outside the hole portions 63, 65 in a plan view. The enlarged space 64 may have any shape and size. A planar shape of the enlarged space 64 according to the present embodiment is formed in a circular shape. As illustrated in FIG. 3, the enlarged space 64 is formed so as to overlap the enlarged space 62 in a plan view. The enlarged space 64 is formed so as to overlap the entire enlarged space 62 in a plan view, for example. A planar size of the enlarged space 64 is larger than a planar size obtained by combining the planar size of the hole portion 63 and a planar size of the hole portion 65. The planar size of the enlarged space 64 may be, for example, about five to twelve times the planar size of the hole portion 63. The planar size of the enlarged space 64 is set to, for example, the same size as the planar size of the enlarged space 62. A diameter of the enlarged space 64 can be, for example, about 1.0 mm to 3.0 mm.

### Configuration of Hole Portion 65

As illustrated in FIG. 1, a lower end portion of the hole portion 65 communicates with the enlarged space 64. The hole portion 65 is formed to extend from the enlarged space 64 toward the placement surface 40A, for example. The hole portion 65 is formed to extend linearly along the thickness direction of the insulating substrate 40, for example. The hole portion 65 is formed to extend from the enlarged space 64 to an upper surface of the insulating layer 43. An upper end portion of the hole portion 65 communicates with the enlarged space 66.

As illustrated in FIG. 4, the hole portion 65 is provided so as not to overlap the hole portion 63 in a plan view. For example, the hole portion 65 is provided at a position rotated by 180 degrees around a center point of the enlarged space 64 from the hole portion 63 in a plan view. The hole portion 65 is disposed such that a separation distance between the hole portion 63 and the hole portion 65 is as large as possible in an area overlapping the enlarged space 64 in a plan view. For example, the hole portion 65 is provided so as to overlap the hole portion 61 in a plan view.

The hole portion 65 may have any shape and size. A planar shape of the hole portion 65 according to the present embodiment is formed in a circular shape. The planar size of the hole portion 65 is set to, for example, the same size as the planar size of the hole portion 61. The planar size of the hole portion 65 is smaller than the planar size of the enlarged space 64. A diameter of the hole portion 65 may be, for example, about 0.05 mm to 0.5 mm.

### Configuration of Enlarged Space 66

As illustrated in FIG. 1, the enlarged space 66 is provided between the insulating layer 43 and the insulating layer 44. The enlarged space 66 is formed so as to be surrounded by the insulating layer 43 and the insulating layer 44. The enlarged space 66 is provided, for example, on the upper surface of the insulating layer 43. The enlarged space 66 is, for example, recessed upward from the lower surface of the insulating layer 44. The enlarged space 66 is formed so as not to penetrate the insulating layer 44 in the thickness direction. The enlarged space 66 is formed to be open below the insulating layer 44, for example. A dimension of the enlarged space 66 along the thickness direction is smaller than a dimension of the insulating layer 44 along the thickness direction. The dimension of the enlarged space 66 along the thickness direction is smaller than a dimension of the hole portion 65 along the planar direction. The dimension of the enlarged space 66 along the thickness direction can be, for example, about 0.02 mm to 0.15 mm.

As illustrated in FIG. 4, the enlarged space 66 is formed to expand from the hole portion 65 in the planar direction. The enlarged space 66 is formed so as to surround the hole portion 65 and the hole portion 67 in a plan view. The enlarged space 66 is formed so as to expand in an area between the hole portion 65 and the hole portion 67 and to expand in an area outside the hole portions 65, 67 in a plan view. The enlarged space 66 may have any shape and size. A planar shape of the enlarged space 66 according to the present embodiment is formed in a circular shape. As illustrated in FIG. 3, the enlarged space 66 is formed so as to overlap the enlarged spaces 62, 64 in a plan view. The enlarged space 66 is formed so as to overlap the entire enlarged spaces 62, 64 in a plan view, for example. A planar size of the enlarged space 66 is larger than a planar size obtained by combining the planar size of the hole portion 65 and a planar size of the hole portion 67. The planar size of the enlarged space 66 may be, for example, about five to twelve times the planar size of the hole portion 65. The planar size of the enlarged space 66 is set to, for example, the same size as the planar size of the enlarged space 62. A diameter of the enlarged space 66 can be, for example, about 1.0 mm to 3.0 mm.

### Configuration of Hole Portion 67

As illustrated in FIG. 1, a lower end portion of the hole portion 67 communicates with the enlarged space 66. The hole portion 67 is formed to extend from the enlarged space 66 toward the placement surface 40A, for example. The hole portion 67 is formed to extend linearly along the thickness direction of the insulating substrate 40, for example. The hole portion 67 is formed to extend from the enlarged space 66 to the upper surface of the insulating layer 44, that is, the placement surface 40A. An upper end portion of the hole portion 67 is formed to be open above the insulating substrate 40. The upper end portion of the hole portion 67 is a discharge port of the gas supply unit 50 that discharges the inert gas to the outside of the gas supply unit 50.

As illustrated in FIG. 4, the hole portion 67 is provided so as not to overlap the hole portion 65 in a plan view. For example, the hole portion 67 is provided at a position rotated by 180 degrees around a center point of the enlarged space 66 from the hole portion 65 in a plan view. The hole portion 67 is disposed such that a separation distance between the hole portion 65 and the hole portion 67 is as large as possible in an area overlapping the enlarged space 66 in a plan view. For example, the hole portion 67 is provided so as to overlap the hole portion 63 in a plan view.

The hole portion 67 may have any shape and size. A planar shape of the hole portion 67 according to the present embodiment is formed in a circular shape. The planar size of the hole portion 67 is set to, for example, the same size as the planar size of the hole portion 61. The planar size of the hole portion 67 is smaller than the planar size of the enlarged space 66. A diameter of the hole portion 67 may be, for example, about 0.05 mm to 0.5 mm.

As illustrated in FIG. 1, in the gas supply unit 50 described above, the inert gas is introduced into the gas supply unit 50 through the gas flow path 51, and the inert gas flows into the hole portion 61 through the gas flow path 51. In the gas supply unit 50, the inert gas flowing into the enlarged space 62 through the hole portion 61 is moved in the planar direction in the enlarged space 62, and then flows into the enlarged space 64 through the hole portion 63. In the gas supply unit 50, the inert gas flowing into the enlarged space 64 is moved in the planar direction in the enlarged space 64, and then flows into the enlarged space 66 through the hole portion 65. In the gas supply unit 50, the inert gas flowing into the enlarged space 66 is moved in the planar direction in the enlarged space 66 and then flows into the hole portion 67, and the inert gas is discharged from the gas supply unit 50 through the hole portion 67. The inert gas discharged from the hole portion 67 can cool the object to be adsorbed by, for example, being filled between the lower surface of the object to be adsorbed placed on the placement surface 40A and the placement surface 40A.

### Operation

Next, an operation of the substrate fixing device 10 will be described.

In the substrate fixing device 10, for example, the object to be adsorbed is placed on the placement surface 40A of the electrostatic chuck 30 in a state of being disposed in a chamber (not illustrated). Then, a raw material gas is introduced into the chamber, and a high frequency voltage is applied to the base plate 20 to generate plasma, thereby performing processing on an object to be adsorbed (for example, a wafer). At this time, the inert gas such as He gas is introduced from the gas supply source (not illustrated) into the gas supply unit 50 including the gas flow path 51 and the gas holes 60. The inert gas is supplied to the lower surface of the object to be adsorbed placed on the placement surface 40A through the gas flow path 51, the hole portion 61, the enlarged space 62, the hole portion 63, the enlarged space 64, the hole portion 65, the enlarged space 66, and the hole portion 67 in this order. When plasma is generated in this way, abnormal discharge may occur in the gas supply unit 50.

Here, when the gas holes are formed to extend linearly along the thickness direction of the electrostatic chuck as in an electrostatic chuck of the related art, a distance of the path through which the inert gas flows is shortened, and a large amount of the inert gas is present inside the gas holes. Therefore, when a high voltage is applied, a probability that the plasma and the inert gas staying inside the gas hole collide with each other increases, and the abnormal discharge is likely to occur inside the gas hole.

In contrast, in the electrostatic chuck 30 according to the present embodiment, the gas hole 60 has the hole portion 61 penetrating the insulating layer 41 in the thickness direction, the enlarged space 62 expanding the space of the gas hole 60 in the planar direction, and the hole portion 63 penetrating the insulating layer 42 in the thickness direction. In addition, the hole portion 61 and the hole portion 63 are provided so as not to overlap each other in a plan view. According to this configuration, since the hole portion 61 and the hole portion 63 communicate with each other through the enlarged space 62, the path through which the inert gas flows can be lengthened. Accordingly, since the inert gas flows over a longer distance than in the related art, the probability that the plasma and the inert gas staying inside the gas hole 60 collide with each other can be lower than in the related art. As a result, occurrence of the abnormal discharge in the gas hole 60 can be suitably prevented, and occurrence of dielectric breakdown or the like due to the abnormal discharge can be suitably prevented.

Further, the dimension of the enlarged space 62 along the thickness direction is set to be smaller than the dimension of the hole portion 61 along the planar direction. According to this configuration, the enlarged space 62 can be formed to be narrow in the thickness direction. Accordingly, for example, when He gas is used as the inert gas, the movement of He molecules in the enlarged space 62 can be prevented, and thus a probability that the He molecules collide with each other can be reduced. Specifically, as compared with a case where the enlarged space 62 is formed to penetrate the insulating layer 42 in the thickness direction, since the movement of the He molecules in the enlarged space 62 can be prevented, the probability that the He molecules collide with each other can be reduced. As a result, the occurrence of the abnormal discharge in the gas hole 60 can be suitably prevented, and the occurrence of dielectric breakdown or the like due to the abnormal discharge can be suitably prevented.

### Method for Manufacturing Substrate Fixing Device 10

Next, a method for manufacturing the substrate fixing device 10 will be described. Here, a method for manufacturing the electrostatic chuck 30 will be described in detail.

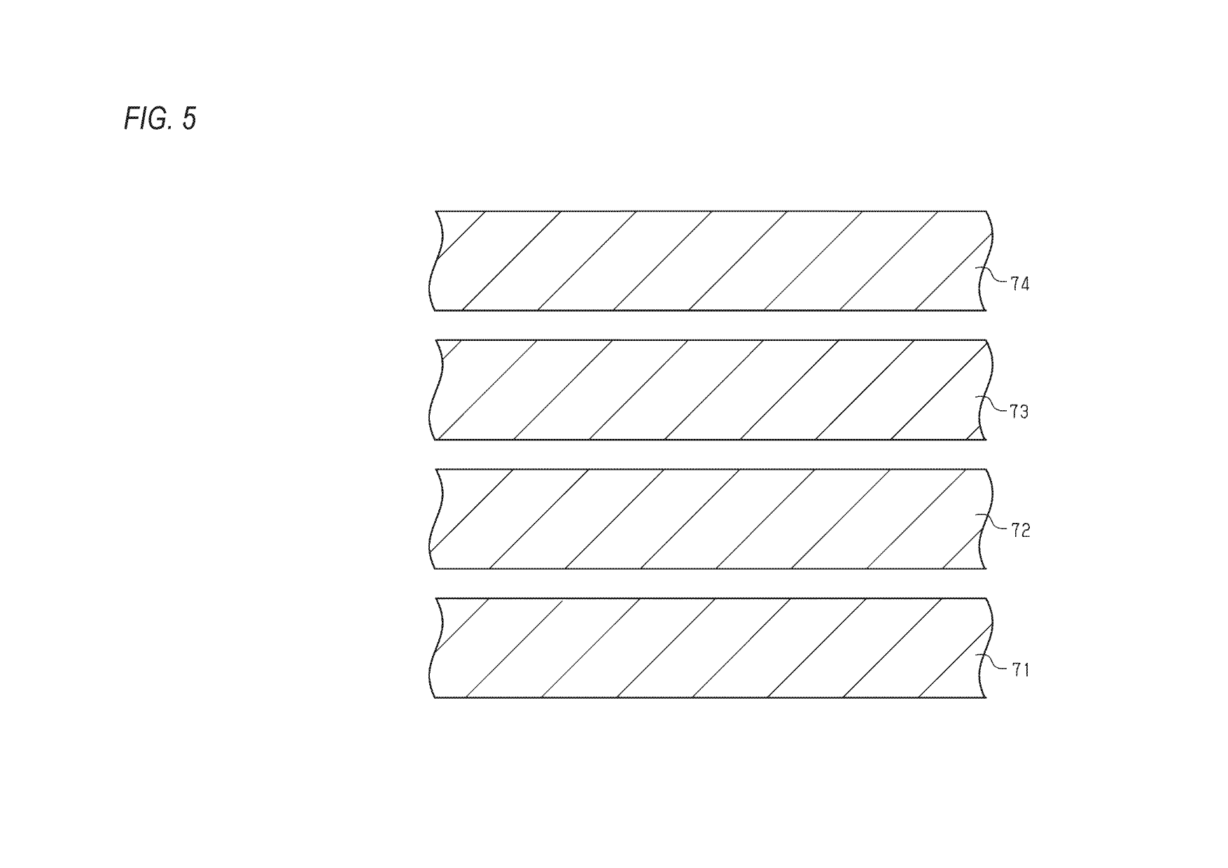

First, in a step illustrated in FIG. 5, green sheets 71, 72, 73, 74 made of a ceramic material and an organic material are prepared. Each of the green sheets 71, 72, 73, 74 is, for example, a sheet-like material made by mixing aluminum oxide (alumina) with a binder, a solvent, and the like. A planar size of each of the green sheets 71, 72, 73, 74 corresponds to the planar size of the insulating substrate 40 illustrated in FIG. 1. The green sheets 71, 72, 73, 74 become the insulating layers 41, 42, 43, 44 illustrated in FIG. 1 by being fired in a step to be described later, respectively.

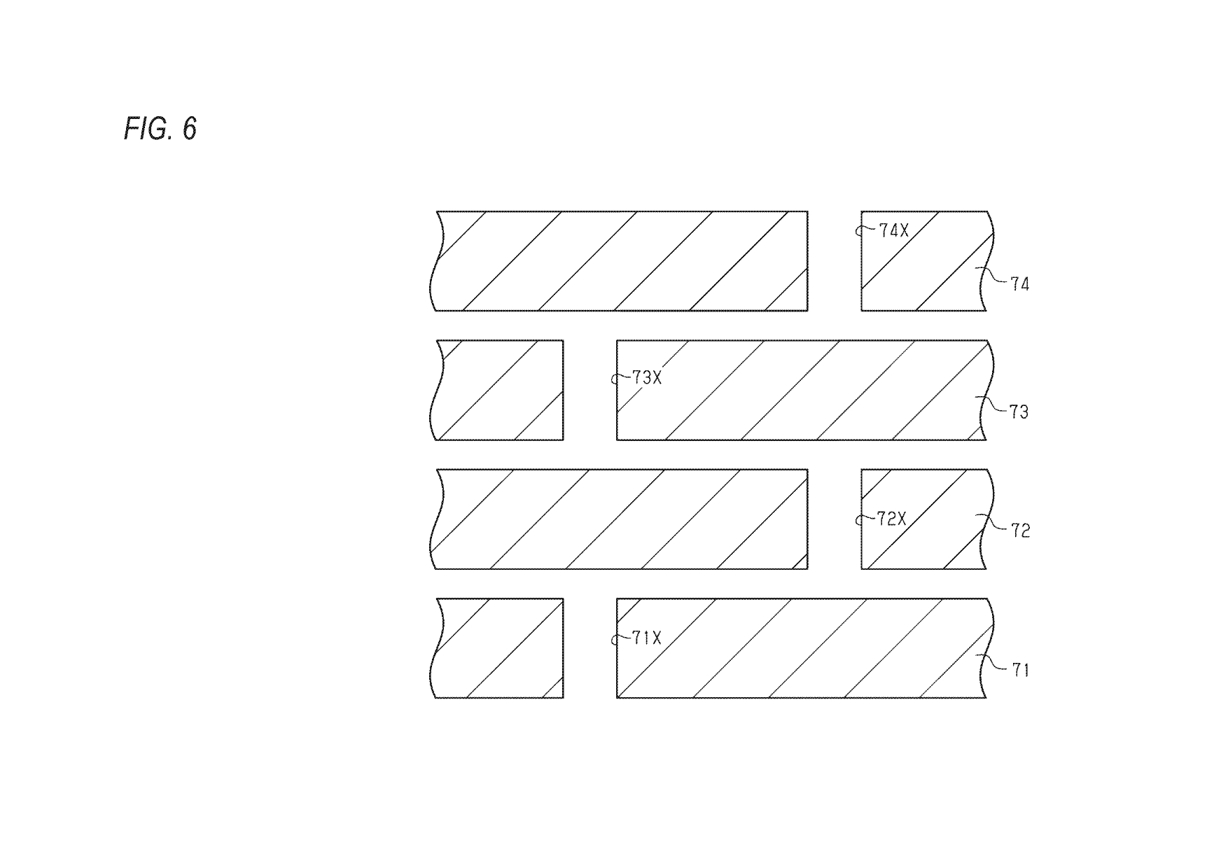

Next, in a step illustrated in FIG. 6, through holes 71X, 72X, 73X, 74X penetrating the green sheets 71, 72, 73, 74 in the thickness direction are formed in the green sheets 71, 72, 73, 74. The through hole 71X is provided at a position corresponding to the hole portion 61 illustrated in FIG. 1. The through hole 72X is provided at a position corresponding to the hole portion 63 illustrated in FIG. 1. The through hole 73X is provided at a position corresponding to the hole portion 65 illustrated in FIG. 1. The through hole 74X is provided at a position corresponding to the hole portion 67 illustrated in FIG. 1. The through holes 71X, 72X, 73X, 74X can be formed by, for example, laser processing or machining.

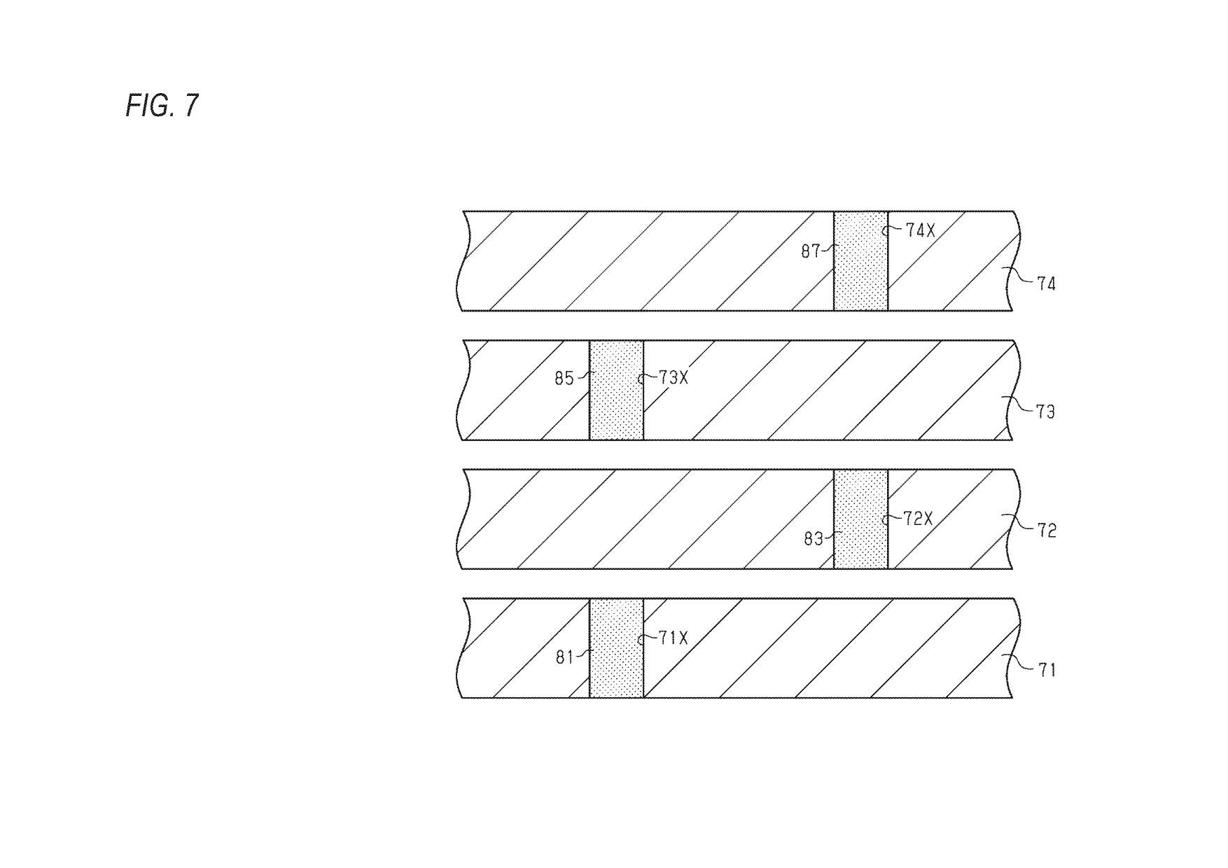

Subsequently, in a step illustrated in FIG. 7, the through hole 71X is filled with a resin paste 81 and the through hole 72X is filled with a resin paste 83 using a squeegee or the like. Similarly, using a squeegee or the like, the through hole 73X is filled with a resin paste 85, and the through hole 74X is filled with a resin paste 87. The resin pastes 81, 83, 85, 87 are each made of, for example, a material that can be volatilized in a firing step to be described later. As a material of the resin pastes 81, 83, 85, 87, for example, a mixture of resin and carbon can be used.

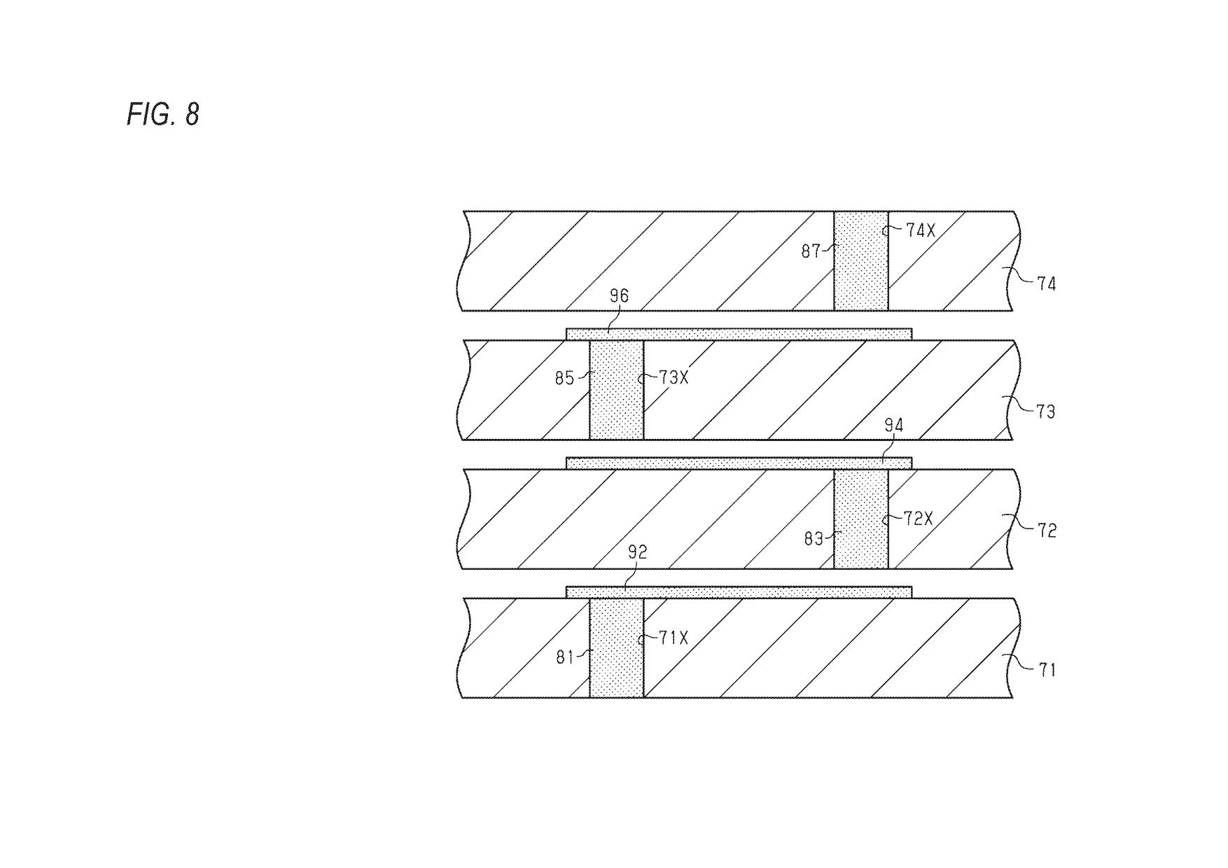

Next, in a step illustrated in FIG. 8, a resin paste 92 is formed on the upper surface of the green sheet 71 and a resin paste 94 is formed on an upper surface of the green sheet 72 by, for example, a printing method (screen printing). Similarly, a resin paste 96 is formed on an upper surface of the green sheet 73 by, for example, a printing method. The resin paste 92 is provided at a position corresponding to the enlarged space 62 illustrated in FIG. 1. The resin paste 92 is provided so as to overlap the resin pastes 81, 83 in a plan view. The resin paste 94 is provided at a position corresponding to the enlarged space 64 illustrated in FIG. 1. The resin paste 94 is provided so as to overlap the resin pastes 83, 85 in a plan view. The resin paste 96 is provided at a position corresponding to the enlarged space 66 illustrated in FIG. 1. The resin paste 96 is provided so as to overlap the resin pastes 85, 87 in a plan view. Like the resin pastes 81, 83, 85, 87, the resin pastes 92, 94, 96 are each made of a material that can be volatilized in a firing step to be described later. As a material of the resin pastes 92, 94, 96, for example, a mixture of resin and carbon can be used. The resin paste 92 may be formed on a lower surface of the green sheet 72. The resin paste 94 may be formed on a lower surface of the green sheet 73, or the resin paste 96 may be formed on a lower surface of the green sheet 74.

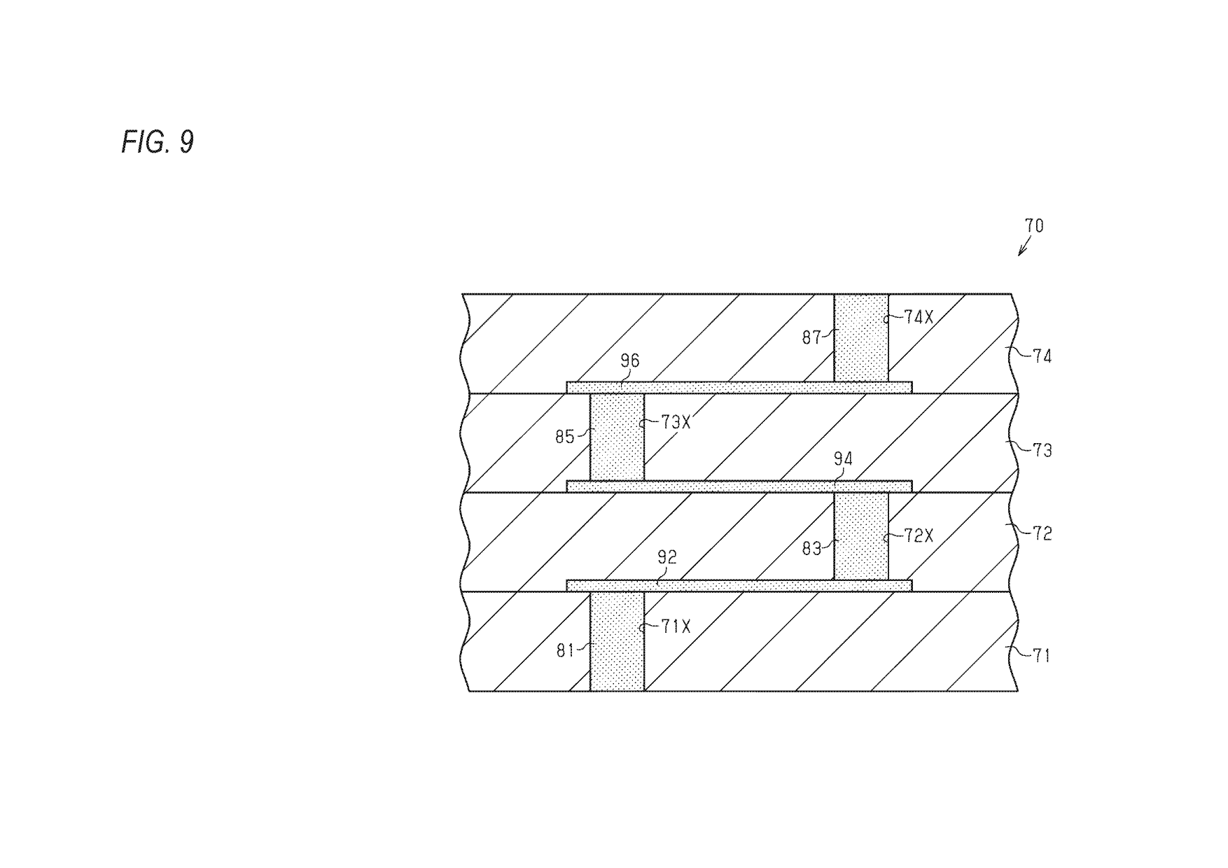

Next, in a step illustrated in FIG. 9, the green sheet 72, the green sheet 73, and the green sheet 74 are arranged in this order on the green sheet 71. At this time, the green sheets 71, 72, 73, 74 are positioned such that the resin pastes 81, 83, 85, 87 and the resin pastes 92, 94, 96 overlap each other in a plan view. Then, the green sheets 71, 72, 73, 74 are stacked to form a structure 70. The green sheets 71, 72, 73, 74 are bonded to each other by being pressurized while being heated. By this step, the resin paste 92 is embedded between the green sheet 71 and the green sheet 72 (the green sheet 72 is stacked on the green sheet 71 so as to sandwich the resin paste 92 therebetween), the resin paste 94 is embedded between the green sheet 72 and the green sheet 73, and the resin paste 96 is embedded between the green sheet 73 and the green sheet 74.

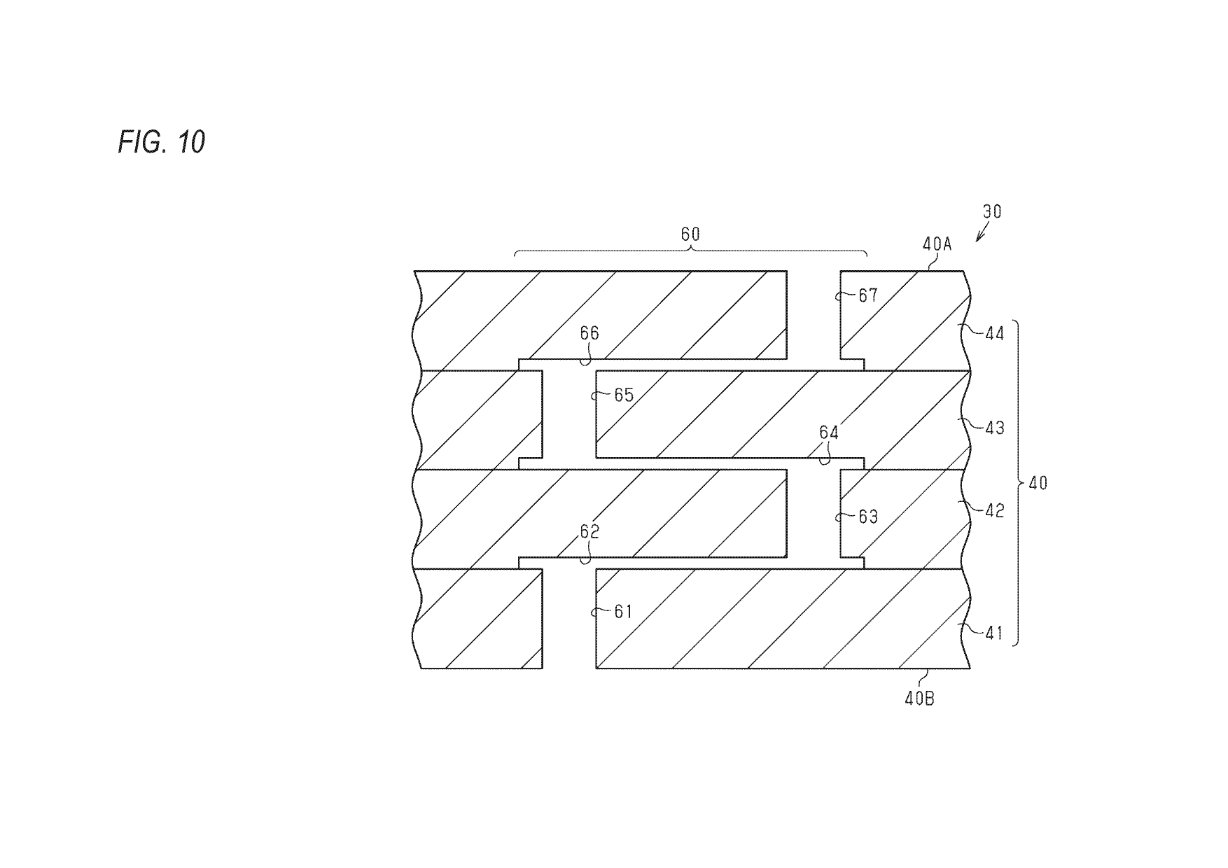

Subsequently, in a step illustrated in FIG. 10, the structure 70 illustrated in FIG. 9 is fired. Accordingly, the green sheets 71, 72, 73, 74 are sintered to form the insulating layers 41, 42, 43, 44, and the insulating substrate 40 in which the insulating layers 41, 42, 43, 44 are stacked is formed. A temperature for firing the structure 70 is, for example, about 1500°C to 1600°C. By the firing in this step, the resin pastes 81, 83, 85, 87, 92, 94, 96 illustrated in FIG. 9 are volatilized and removed. Accordingly, the gas hole 60 in which the hole portion 61, the enlarged space 62, the hole portion 63, the enlarged space 64, the hole portion 65, the enlarged space 66, and the hole portion 67 communicate with each other is formed inside the insulating substrate 40.

The electrostatic chuck 30 can be manufactured by the above-described manufacturing steps.

In the present embodiment, the insulating layer 41 is an example of a first insulating layer, the insulating layer 42 is an example of a second insulating layer, the hole portion 61 is an example of a first hole portion, the hole portion 63 is an example of a second hole portion, and the hole portion 63 is an example of a third hole portion. The enlarged space 62 is an example of a first enlarged space, and the enlarged space 64 is an example of a second enlarged space. The green sheet 71 is an example of a first green sheet, the green sheet 72 is an example of a second green sheet, the through hole 71X is an example of a first through hole, and the through hole 72X is an example of a second through hole. The resin paste 81 is an example of a first resin paste, the resin paste 83 is an example of a second resin paste, and the resin paste 92 is an example of a third resin paste.

### Operations and Effects According to Present Embodiment

Next, operations and effects according to the present embodiment will be described.

(1) The electrostatic chuck 30 includes the insulating substrate 40 having the placement surface 40A on which an object to be adsorbed is placed and the opposite surface 40B provided on the opposite side of the placement surface 40A, and the gas hole 60 penetrating the insulating substrate 40 in the thickness direction. The gas hole 60 includes the hole portion 61 that extends from the opposite surface 40B toward the placement surface 40A, the enlarged space 62 that communicates with the hole portion 61 and expands the space of the gas hole 60 in the planar direction, and the hole portion 63 that communicates with the enlarged space 62 and extends from the enlarged space 62 toward the placement surface 40A. The hole portion 61 is provided so as not to overlap the hole portion 63 in a plan view. The planar size of the enlarged space 62 is larger than the planar size obtained by combining the planar size of the hole portion 61 and the planar size of the hole portion 63. The dimension of the enlarged space 62 along the thickness direction is smaller than the dimension of the hole portion 61 along the planar direction.

According to this configuration, since the hole portion 61 and the hole portion 63 communicate with each other through the enlarged space 62 that expands the space of the gas hole 60 in the planar direction, the path of the gas hole 60 can be complicated, and a flow distance of the inert gas can be increased. Accordingly, since the inert gas flows over a longer distance than in the related art, the probability that the plasma and the inert gas staying inside the gas hole 60 collide with each other can be lower than in the related art. As a result, the occurrence of the abnormal discharge in the gas hole 60 can be suitably prevented, and the occurrence of dielectric breakdown or the like due to the abnormal discharge can be suitably prevented.

(2) The dimension of the enlarged space 62 along the thickness direction is set to be smaller than the dimension of the hole portion 61 along the planar direction. According to this configuration, the enlarged space 62 can be formed to be narrow in the thickness direction. Accordingly, for example, when He gas is used as the inert gas, the movement of He molecules in the enlarged space 62 can be prevented, and thus a probability that the He molecules collide with each other can be reduced. Specifically, as compared with the case where the enlarged space 62 is formed to penetrate the insulating layer 42 in the thickness direction, since the movement of the He molecules in the enlarged space 62 can be prevented, the probability that the He molecules collide with each other can be reduced. As described above, while the path of the gas hole 60 is lengthened by providing the enlarged space 62, the movement of He molecules in the enlarged space 62 can be prevented by forming the enlarged space 62 to be narrow in the thickness direction. As a result, the occurrence of the abnormal discharge in the gas hole 60 can be suitably prevented, and the occurrence of dielectric breakdown or the like due to the abnormal discharge can be suitably prevented.

(3) When the hole portion 61 and the hole portion 63 are formed so as not to overlap each other in a plan view, it is also conceivable to form the entire shape of the gas hole 60 in a spiral shape. In this case, the enlarged space 62 is formed in a curved shape extending in a curved manner from the hole portion 61 toward the hole portion 63 in a plan view. In such a case, the inert gas flows through the spiral path in one direction.

On the other hand, in the electrostatic chuck 30 according to the present embodiment, the enlarged space 62 is formed to expand in the area between the hole portion 61 and the hole portion 63 and to expand in the area outside the hole portion 61 and the hole portion 63 in a plan view. Accordingly, as compared with a case where the gas hole 60 is formed in a spiral shape, the planar size of the enlarged space 62 can be increased, and the enlarged space 62 can be formed to be wide in the planar direction. Therefore, it is possible to secure a wide space in the enlarged space 62 with respect to the amount of He molecules introduced into the gas hole 60. Therefore, the probability that the He molecules collide with each other in the enlarged space 62 can be suitably reduced.

(4) The gas hole 60 further includes the enlarged space 64 that communicates with the hole portion 63 and expands the space of the gas hole 60 in the planar direction, and the hole portion 65 that communicates with the enlarged space 64 and extends from the enlarged space 64 toward the placement surface 40A. The hole portion 65 is provided so as not to overlap the hole portion 63 and so as to overlap the hole portion 61 in a plan view.

According to this configuration, the gas hole 60 is formed in a structure in which the hole portion 61, the enlarged space 62, the hole portion 63, the enlarged space 64, and the hole portion 65 communicate with each other. Accordingly, the path of the gas hole 60 can be complicated, and the flow distance of the inert gas can be increased. Therefore, since the inert gas flows over a longer distance than in the related art, the probability that the plasma and the inert gas staying inside the gas hole 60 collide with each other can be lower than in the related art.

### Modification

The above embodiment may be modified as follows. The above embodiment and the following modification can be combined as long as there is no technical contradiction.

In the above embodiment, the planar shapes of the enlarged spaces 62, 64, 66 are each a circular shape, but the present invention is not limited thereto. For example, the planar shapes of the enlarged spaces 62, 64, 66 may each be a polygonal shape or an elliptical shape.

In the above embodiment, the planar shapes of the enlarged spaces 62, 64, 66 are the same, but the present invention is not limited thereto. For example, the planar shapes of the enlarged spaces 62, 64, 66 may be different from each other.

In the above embodiment, the number of hole portions 61, 63 communicating with one enlarged space 62 is one, but the number of hole portions 61, 63 is not particularly limited. Similarly, the number of hole portions 63, 65 communicating with one enlarged space 64 and the number of hole portions 65, 67 communicating with one enlarged space 66 are not particularly limited.

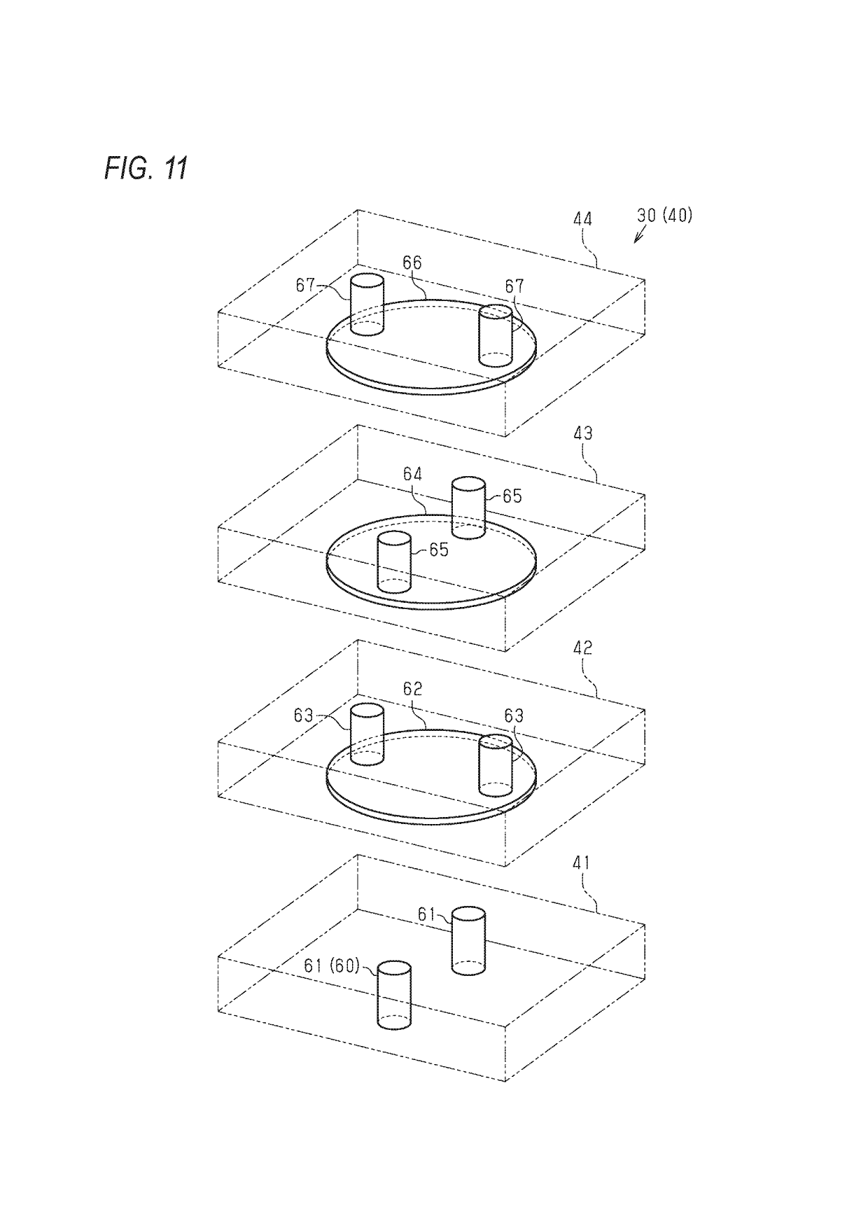

For example, as illustrated in FIG. 11, two or more hole portions 61 may communicate with one enlarged space 62, and two or more hole portions 63 may communicate with one enlarged space 62. Further, two or more hole portions 63 may communicate with one enlarged space 64, and two or more hole portions 65 may communicate with one enlarged space 64. Further, two or more hole portions 65 may communicate with one enlarged space 66, and two or more hole portions 67 may communicate with one enlarged space 66.

In this case, each of the two hole portions 61 is provided so as not to overlap the two hole portions 63 in a plan view. The two hole portions 63 are respectively provided, for example, at positions rotated by 90 degrees around the center point of the enlarged space 62 from the hole portions 61 in a plan view. The two hole portions 65 are provided so as not to overlap the two hole portions 63 in a plan view, and are respectively provided so as to overlap the two hole portions 61 in a plan view. The two hole portions 65 are respectively provided, for example, at positions rotated by 90 degrees around the center point of the enlarged space 64 from the hole portions 63 in a plan view. The two hole portions 67 are provided so as not to overlap the two hole portions 65 in a plan view, and are respectively provided so as to overlap the two hole portions 63 in a plan view. The two hole portions 67 are respectively provided, for example, at positions rotated by 90 degrees around the center point of the enlarged space 66 from the hole portions 65 in a plan view.

In the above embodiment, each gas hole 60 has a structure including three enlarged spaces 62, 64, 66, but the number of enlarged spaces included in each gas hole 60 is not limited thereto. For example, the number of enlarged spaces included in each gas hole 60 may be one or two, or may be four or more. For example, the enlarged space included in each gas hole 60 may be only the enlarged space 62.

In the above embodiment, the insulating layer 41 and the insulating layer 42 may be bonded to each other by an adhesive layer. The insulating layer 42 and the insulating layer 43 may be bonded to each other by an adhesive layer. The insulating layer 43 and the insulating layer 44 may be bonded to each other by an adhesive layer.

In the above embodiment, the insulating substrate 40 has a structure in which four insulating layers 41, 42, 43, 44 are stacked, but the present invention is not limited thereto. For example, the insulating substrate 40 may have a structure in which two or three insulating layers are stacked. For example, the insulating substrate 40 may have a structure in which five or more insulating layers are stacked.

The structure of the electrostatic chuck 30 of the above embodiment is not particularly limited. For example, a heating element (heater) that generates heat by applying a voltage from the outside of the substrate fixing device 10 and heats the placement surface 40A of the insulating substrate 40 to a predetermined temperature may be provided inside the insulating substrate 40. For example, an embossed structure may be provided on the placement surface 40A of the insulating substrate 40.

A structure of the base plate 20 of the above embodiment is not particularly limited. For example, the shape of the gas flow path 51 is not particularly limited. A heater may be provided inside the base plate 20.

The substrate fixing device 10 in the above embodiment is applied to a semiconductor manufacturing device, for example, a dry etching device. Examples of the dry etching device include a parallel plate type reactive ion etching (RIE) device. The substrate fixing device 10 can also be applied to a semiconductor manufacturing device such as a plasma chemical vapor deposition (CVD) device or a sputtering device.

What is claimed is:

1. An electrostatic chuck comprising:
an insulating substrate having a placement surface on which an object to be adsorbed is placed and an opposite surface provided on an opposite side of the placement surface; and
a gas hole penetrating the insulating substrate in a thickness direction, wherein
the gas hole includes
a first hole portion that extends from the opposite surface toward the placement surface,
a first enlarged space that communicates with the first hole portion and expands a space of the gas hole in a planar direction orthogonal to the thickness direction, and
a second hole portion that communicates with the first enlarged space and extends from the first enlarged space toward the placement surface,
the first hole portion is provided so as not to overlap the second hole portion in a plan view,
a planar size of the first enlarged space is larger than a planar size obtained by combining a planar size of the first hole portion and a planar size of the second hole portion, and
a dimension of the first enlarged space along the thickness direction is smaller than a dimension of the first hole portion along the planar direction.

2. The electrostatic chuck according to claim 1, wherein
a planar shape of the first enlarged space is formed in a circular shape, and
the first enlarged space is formed to expand in an area between the first hole portion and the second hole portion and to expand in an area outside the first hole portion and the second hole portion in a plan view.

3. The electrostatic chuck according to claim 2, wherein
the gas hole includes
a second enlarged space that communicates with the second hole portion and expands the space of the gas hole in the planar direction, and
a third hole portion that communicates with the second enlarged space and extends from the second enlarged space toward the placement surface, and
the third hole portion is provided so as not to overlap the second hole portion and is provided so as to overlap the first hole portion in a plan view.

4. The electrostatic chuck according to claim 3, wherein
the second enlarged space is provided so as to overlap an entire first enlarged space in a plan view.

5. The electrostatic chuck according to claim 1, wherein
the gas hole includes one first hole portion, one first enlarged space, and one second hole portion, and
the second hole portion is provided at a position rotated by 180 degrees about a center point of the first enlarged space from the first hole portion in a plan view.

6. The electrostatic chuck according to claim 1, wherein
the insulating substrate includes a first insulating layer having the opposite surface and a second insulating layer stacked on the first insulating layer,
the first hole portion is formed to penetrate the first insulating layer in the thickness direction,
the first enlarged space is formed on an upper surface of the first insulating layer and is recessed upward from a lower surface of the second insulating layer, and
the second hole portion is formed to penetrate the second insulating layer in the thickness direction.

7. The electrostatic chuck according to claim 6, wherein
the gas hole includes
two first hole portions that penetrate the first insulating layer in the thickness direction,
one first enlarged space that is provided between the first insulating layer and the second insulating layer, and
two second hole portions that penetrate the second insulating layer in the thickness direction,
the two first hole portions communicate with the one first enlarged space,
the two second hole portions communicate with the one first enlarged space, and
each of the two first hole portions is provided so as not to overlap the two second hole portions in a plan view.

8. A substrate fixing device comprising:
the electrostatic chuck according to claim 1; and
a base plate bonded to the opposite surface of the electrostatic chuck.

9. A method for manufacturing an electrostatic chuck comprising:
a step of preparing a first green sheet and a second green sheet;
a step of forming a first through hole penetrating the first green sheet in a thickness direction and forming a second through hole penetrating the second green sheet in the thickness direction;
a step of filling the first through hole with a first resin paste and filling the second through hole with a second resin paste;
a step of forming a third resin paste on an upper surface of the first green sheet or a lower surface of the second green sheet so as to overlap the first resin paste and the second resin paste in a plan view;
a step of stacking the second green sheet on the first green sheet with the third resin paste interposed therebetween; and
a step of firing the first green sheet and the second green sheet stacked on each other, wherein
in the step of firing, the first resin paste, the second resin paste, and the third resin paste are volatilized to form a gas hole including a first hole portion that penetrates the first green sheet in the thickness direction, a first enlarged space that communicates with the first hole portion, and a second hole portion that communicates with the first enlarged space and penetrates the second green sheet in the thickness direction.
